(19) United States
(12) Patent Application Publication
(10) Pub. No.: US 2026/0123251 A1
(43) Pub. Date: Apr. 30, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Soo Yeong HONG, Yongin-si (KR); Hyang A PARK, Yongin-si (KR); Seo Young LIM, Yongin-si (KR); Go Een JEONG, Yongin-si (KR)

(21) Appl. No.: 19/312,471

(22) Filed: Aug. 28, 2025

(30) Foreign Application Priority Data
Oct. 29, 2024 (KR) 10-2024-0149578

(51) Int. Cl. H10K 59/80; H10K 39/34

(52) U.S. Cl. CPC H10K 59/879; H10K 39/34

(57) ABSTRACT

A display device including: a substrate including a sub-pixel including a light emitting layer and a light sensing pixel including a light receiving layer; a first light receiving meta lens overlapping the light receiving layer; and a second light receiving meta lens overlapping the first light receiving meta lens, wherein light incident on the first light receiving meta lens is emitted at a first light receiving angle with respect to a normal line of the substrate, light incident on the second light receiving meta lens is emitted at a second light receiving angle with respect to the normal line of the substrate, and the first light receiving angle is greater than the second light receiving angle.

This application claims priority under 35 U.S.C. § 119 to Korean Patent Application No. 10-2024-0149578, filed on Oct. 29, 2024, the disclosure of which is incorporated by reference herein in its entirety.

### 1. TECHNICAL FIELD

The present disclosure relates to a display device and an electronic device including the same.

### 2. DESCRIPTION OF THE RELATED ART

As interest in information display continues to grow, research and development on display devices are ongoing.

### SUMMARY

Embodiments of the disclosure enhance the front surface light emission efficiency in the private mode of a display device and improve sensing performance.

An embodiment of the disclosure provides a display device including: a substrate including a sub-pixel including a light emitting layer and a light sensing pixel including a light receiving layer; a first light receiving meta lens overlapping the light receiving layer; and a second light receiving meta lens overlapping the first light receiving meta lens, wherein light incident on the first light receiving meta lens is emitted at a first light receiving angle with respect to a normal line of the substrate, light incident on the second light receiving meta lens is emitted at a second light receiving angle with respect to the normal line of the substrate, and the first light receiving angle is greater than the second light receiving angle.

The first light receiving meta lens overlaps the second light receiving meta lens.

Each of the first light receiving meta lens and the second light receiving meta lens includes a thin film, and holes in the thin film.

The first light receiving angle is 40° or less.

The second light receiving angle is 0°.

The display device further includes a third light receiving meta lens overlapping the second light receiving meta lens.

The third light receiving meta lens collects light at a third light receiving angle with respect to the normal line of the substrate, and the third light receiving angle is greater than the second light receiving angle.

The third light receiving angle is 60°.

The third light receiving meta lens overlaps the first light receiving meta lens.

The display device further includes: a first light emitting meta lens overlapping the light emitting layer; and a second light emitting meta lens overlapping the first light emitting meta lens, wherein the first light emitting meta lens collects light at a first light emitting angle with respect to the normal line of the substrate, light incident on the second light emitting meta lens is emitted at a second light emitting angle with respect to the normal line of the substrate, and the first light emitting angle is greater than the second light emitting angle.

The first light emitting angle is 25°.

The second light emitting angle is 0°.

The display device further including a third light emitting meta lens overlapping the second light emitting meta lens.

Light incident on the third light emitting meta lens is emitted at a third light emitting angle with respect to the normal line of the substrate, and the third light emitting angle is greater than the second light emitting angle.

The third light emitting angle is 25° or less.

An embodiment of the disclosure provides a display device including: a first pixel and a second pixel having a viewing angle narrower than a viewing angle of the first pixel, wherein the second pixel includes: a sub-pixel including a light emitting layer; a light sensing pixel including a light receiving layer; a first light emitting meta lens overlapping the light emitting layer; a second light emitting meta lens overlapping the first light emitting meta lens; a first light receiving meta lens overlapping the light receiving layer; and a second light receiving meta lens overlapping the first light receiving meta lens.

The first light emitting meta lens and the first light receiving meta lens are located in a same layer.

The second light emitting meta lens and the second light receiving meta lens are located in a same layer.

The first light emitting meta lens and the second light receiving meta lens do not overlap the first pixel.

The first light receiving meta lens and the second light receiving meta lens do not overlap the first pixel.

An embodiment of the disclosure provides an electronic device including: a display panel including a first pixel and a second pixel having a viewing angle narrower than a viewing angle of the first pixel, wherein the second pixel includes: a sub-pixel including a light emitting layer; a light sensing pixel including a light receiving layer; a first light emitting meta lens overlapping the light emitting layer; a second light emitting meta lens overlapping the first light emitting meta lens; a first light receiving meta lens overlapping the light receiving layer; and a second light receiving meta lens overlapping the first light receiving meta lens.

According to the embodiments described above, controlling the light path using a meta lens can enhance the front surface light emission efficiency in the private mode of a display device and improve sensing performance.

The effects of the embodiments are not limited to the examples provided above; additional effects are also encompassed within this specification.

### BRIEF DESCRIPTION OF THE DRAWINGS

The above and other features of the disclosure will become more apparent through a detailed description of the embodiments with reference to the accompanying drawings, in which:

FIG. 1 is a block diagram schematically illustrating an embodiment of a display device;

FIG. 2 is a block diagram schematically illustrating an embodiment of a sub-pixel;

FIG. 3 is a plan view schematically illustrating an embodiment of a display panel;

FIG. 4 is a plan view schematically illustrating an embodiment of a pixel;

FIGS. 5 and 6 are cross-sectional views taken along line A-A′ of FIG. 4;

FIG. 7 is a cross-sectional view schematically illustrating a light sensing pixel;

FIG. 8 is a cross-sectional view schematically illustrating a second pixel;

FIG. 9 is a cross-sectional view schematically illustrating a first pixel;

FIG. 10 is a perspective view schematically illustrating an application example of a display device;

FIG. 11 is a block diagram of an electronic device according to an embodiment; and

FIG. 12 shows schematic views of various embodiments of an electronic device.

### DETAILED DESCRIPTION OF THE EMBODIMENTS

Hereinafter, embodiments according to the disclosure are described in detail with reference to the accompanying drawings. In the following description, only the portions necessary for understanding the operation of the disclosure are included, while other details are omitted to avoid obscuring the subject matter of the disclosure. The disclosure is not limited to the embodiments described herein and may be implemented in various forms.

Throughout the specification, the term “connected” between two portions includes both “directly connected” and “indirectly connected,” where another element may be interposed. Terms used herein are for describing specific embodiments and are not intended to limit the disclosure. Unless otherwise state, when a certain portion “includes” a component, it may also include additional components without excluding others. The expressions “at least any of X, Y, and Z” and “at least any selected from a group consisting of X, Y, and Z” may be interpreted to mean one of X, one Y, one Z, or any combination of two or more of X, Y, and Z (for example, XYZ, XYY, YZ, and ZZ). Here, the term “and/or” includes all combinations of one or more of the referenced elements.

Here, terms such as first and second may be used to describe various components, but these components are not limited to these terms. These terms are used to distinguish one component from another component. Therefore, a first component may refer to a second component.

Spatially relative terms such as “under”, “on”, and the like are used for descriptive purposes to indicate the relationship between elements or features as shown in the drawings. These terms are not limited to the orientations shown and may encompass other directions depending on use, operation, or manufacturing conditions. For example, if a depicted device is flipped upside down, elements initially described as being “under” other elements would instead be positioned “on” them. Therefore, in an embodiment, the term “under” may include both directions of on and under. In addition, the device may be oriented in other directions (for example, rotated 90 degrees or placed in another position), and the spatially relative terms should be interpreted accordingly.

Various embodiments are described with reference to drawings that schematically illustrate idealized embodiments. Accordingly, the actual shapes of components may vary due to tolerances, manufacturing techniques of other factors. Therefore, the embodiments disclosed herein should be construed as being limited to the specific shapes shown, but should be interpreted to included, for example, variations resulting from manufacturing or design modifications. As such, the shapes shown in the drawings may not represent the actual proportions of a device, and the present embodiments are not limited thereto.

The present disclosure pertains to a display device incorporating an advanced optical system using meta lenses to enhance light emission efficiency and sensing capabilities. The display comprises a substrate that includes sub-pixels for light emission and light-sensing pixels for detecting external light. A first and second light-receiving meta lens are positioned sequentially on the light-sensing layer, controlling the path of incident light. The design enables emitted light to be directed at different angles, with the first light-receiving angle being greater than the second, optimizing light collection and improving sensor performance. Similarly, the display includes light-emitting meta lenses that adjust the emission angles to enhance front-surface visibility while maintaining a private viewing mode.

By strategically stacking multiple meta lenses, the present disclosure allows the display to achieve improved private mode efficiency, reducing the need for conventional light-blocking layers that limit resolution. The meta lens system precisely controls the angles of light emission and reception, increasing the effectiveness of both display visibility and sensing performance. This structure can be implemented in various electronic devices, including automotive displays, mobile devices, and smart glasses, providing enhanced image clarity while enabling functions such as fingerprint sensing, motion detection, and privacy-enhanced viewing.

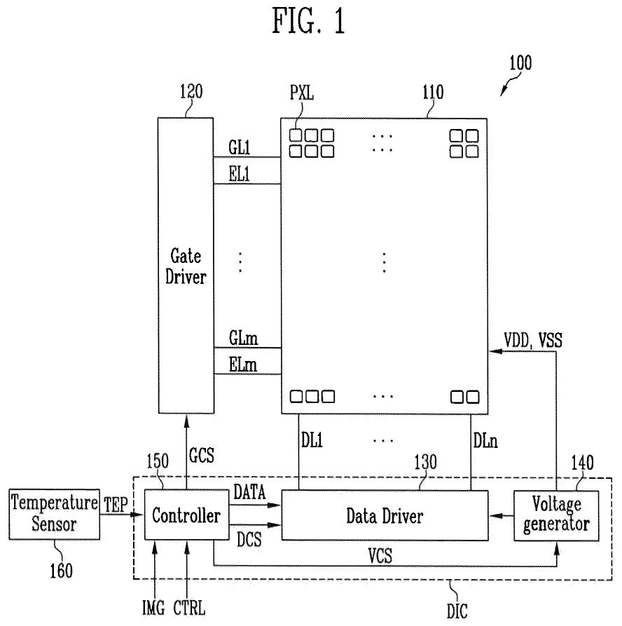

FIG. 1 is a block diagram schematically illustrating an embodiment of a display device.

Referring to FIG. 1, the display device 100 may include a display panel 110, a gate driver 120, a data driver 130, a voltage generator 140, and a controller 150. The display device 100 may be applied to an electronic device such as an electronic device, a smartphone, a computing system, a display system, smart glasses, a head mounted display (HMD), or a vehicle display device.

The display panel 110 may include pixels PXL. The pixels PXL may be connected to the gate driver 120 through first to m-th gate lines GL1 to GLm. The pixels PXL may be connected to the data driver 130 through first to n-th data lines DL1 to DLn.

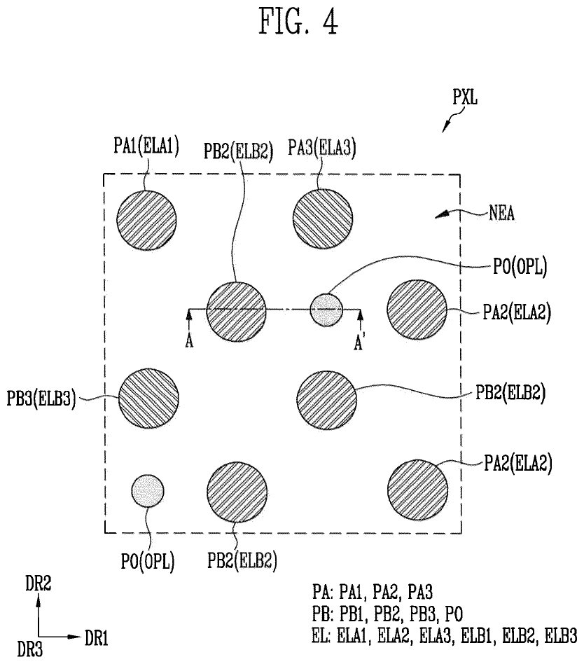

The pixel PXL may include sub-pixels. Each of the sub-pixels may include at least one light emitting element. Accordingly, each of the sub-pixels may generate light of a specific color such as red, green, blue, cyan, magenta, or yellow. In an embodiment, the display panel 110 may be a switchable private display panel capable of switching between a normal mode (or a first mode) and a private mode (or a second mode) in which a viewing angle is limited. The pixel PXL may include first pixels (or general pixels) that emit light in the normal mode and second pixels (or private pixels) that emit light in the private mode. A detailed description thereof is described later with reference to FIG. 4 and the like.

The gate driver 120 may be connected to the sub-pixels arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal indicating a start of each frame, a horizontal synchronization signal for outputting the gate signals in synchronization with a timing of data signals application, and the like.

In an embodiment, first to m-th emission control lines EL1 to ELm connected to the sub-pixels of the row direction may be further provided. In this case, the gate driver 120 may include an emission control driver configured to control the first to m-th emission control lines EL1 to ELm, and the emission control driver may operate under control of the controller 150.

The gate driver 120 may be located on one side of the display panel 110. However, embodiments are not limited thereto. For example, the gate driver 120 may be divided into two or more drivers physically and/or logically separated, and such drivers may be located on a first side of the display panel 110 and a second side of the display panel 110 opposite to the first side. As described above, the gate driver 120 may be located around the display panel 110 in various configurations depending on the embodiment.

The data driver 130 may be connected to the sub-pixels located in a column direction through the first to n-th data lines DL1 to DLn. The data driver 130 receives image data DATA and a data control signal DCS from the controller 150. The data driver 130 operates in response to the data control signal DCS. In an embodiment, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. The data signals corresponding to the image data DATA may be applied to the data lines DL1 to DLm when the gate signal is applied to each of the first to m-th gate lines GL1 to GLm. Accordingly, the corresponding sub-pixels may generate light corresponding to the data signals, thereby displaying an image on the display panel 110.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate and supply voltages to various components of the display device 100. For example, the voltage generator 140 may receive an input voltage from an external source, adjust the received voltage, and regulate the adjusted voltage to ensure stable operation of the display device 100.

The voltage generator 140 may generate a first power voltage VDD and a second power voltage VSS, which are supplied to the sub-pixels. The first power voltage VDD may have a relatively high voltage level, and the second power voltage VSS may have a voltage level lower than that of the first power voltage VDD. In another embodiment, the first power voltage VDD or the second power voltage VSS may be provided by an external device, rather than being generated within the display device 100.

In addition, the voltage generator 140 may generate various voltages for different functions with the display device 100. For example, the voltage generator 140 may generate an initialization voltage applied to the sub-pixels. For example, during a sensing operation, which detects the electrical characteristics of transistors and/or light emitting elements of the sub-pixels, a reference voltage may be applied to the first to n-th data lines DL1 to DLn, and the voltage generator 140 may be responsible for generating this reference voltage.

The controller 150 controls overall operations of the display device 100. The controller 150 may receive input image data IMG and a control signal CTRL from an external source to manage the display of the input image data IMG. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. In an embodiment, the controller 150 may output the image data DATA by aligning the input image data IMG so that the input image data IMG is suitable for the sub-pixels of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within a single driver integrated circuit DIC. In another embodiment, at least one of the data driver 130, the voltage generator 140, or the controller 150 may be provided as a separate component distinct from the driver integrated circuit DIC.

The display device 100 may include at least one temperature sensor 160. The temperature sensor 160 may be configured to sense a temperature around the temperature sensor 160 and generate temperature data TEP indicating the sensed temperature. In an embodiment, the temperature sensor 160 may be located adjacent to the display panel 110 and/or the driver integrated circuit DIC.

The controller 150 may control various operations of the display device 100 in response to the temperature data TEP. In an embodiment, the controller 150 may adjust a luminance of the image output from the display panel 110 in response to the temperature data TEP. For example, the controller 150 may control the data signals and the first and second driving voltages VDD and VSS by controlling components such as the data driver 130 and/or the voltage generator 140.

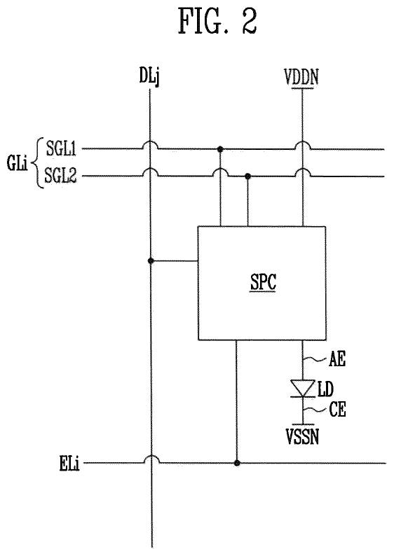

FIG. 2 is a block diagram schematically illustrating an embodiment of a sub-pixel.

In FIG. 2, a sub-pixel arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel may include a pixel circuit SPC and a light emitting element LD. The light emitting element LD may be connected between a first power voltage node VDDN and a second power voltage node VSSN. Here, the first power voltage node VDDN is a node that transmits the first power voltage VDD of FIG. 1, and the second power voltage node VSSN is a node that transmits the second power voltage VSS of FIG. 1.

An anode electrode E1 of the light emitting element LD may be connected to the first power voltage node VDDN through the pixel circuit SPC, and a cathode electrode E2 of the light emitting element LD may be connected to the second power voltage node VSSN. For example, the anode electrode E1 of the light emitting element LD may be connected to the first power voltage node VDDN through one or more transistors included in the pixel circuit SPC.

The pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The pixel circuit SPC may be configured to control the light emitting element LD according to signals received through these signal lines.

The pixel circuit SPC may operate in response to a gate signal received through the i-th gate line GLi. The i-th gate line GLi may include one or more sub-gate lines. In an embodiment, as shown in FIG. 2, the i-th gate line GLi may include first and second sub-gate lines SGL1 and SGL2. The pixel circuit SPC may operate in response to gate signals received through the first and second sub-gate lines SGL1 and SGL2. As described above, when the i-th gate line GLi includes two or more sub-gate lines, the pixel circuit SPC may operate in response to gate signals received through the corresponding sub-gate lines.

The pixel circuit SPC may operate in response to an emission control signal received through the i-th emission control line ELi. In an embodiment, the i-th emission control line ELi may include one or more sub-emission control lines. The pixel circuit SPC may operate in response to emission control signals received through the corresponding sub-emission control lines when the i-th emission control line ELi includes two or more sub-emission control lines.

The pixel circuit SPC may receive a data signal through the j-th data line DLj. The pixel circuit SPC may store a voltage corresponding to the data signal in response to at least one of the gate signals received through the first and second sub-gate lines SGL1 and SGL2. The pixel circuit SPC may control a current flowing from the first power voltage node VDDN to the second power voltage node VSSN through the light emitting element LD based on the stored voltage, in response to the emission control signal received through the i-th emission control line ELi. Accordingly, the light emitting element LD may emit light with a luminance corresponding to the data signal.

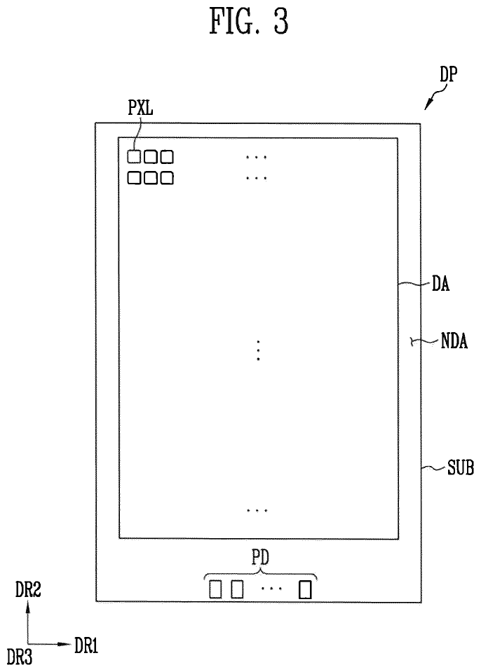

FIG. 3 is a plan view schematically illustrating an embodiment of a display panel.

Referring to FIG. 3, an embodiment of the display panel 110 of FIG. 1 (now referenced by “DP”) may include a display area DA and a non-display area NDA. The display panel DP displays an image through the display area DA. The non-display area NDA may be located around the display area DA.

The display panel DP may include a substrate SUB, the pixels PXL, and pads PD. The pixels PXL may be located in the display area DA on the substrate SUB. The pixels PXL may be arranged in a matrix form along a first direction DR1 and a second direction DR2 crossing the first direction DR1. However, embodiments are not limited thereto. The first direction DR1 may be a row direction, and the second direction DR2 may be a column direction.

A component for controlling the pixels PXL may be located in the non-display area NDA on the substrate SUB. For example, lines such as the first to m-th gate lines GL1 to GLm and the first to n-th data lines DL1 to DLn of FIG. 1 may be located in the non-display area NDA.

At least one of the gate driver 120, the data driver 130, the voltage generator 140, the controller 150, or the temperature sensor 160 of FIG. 1 may be integrated in the non-display area NDA of the display panel DP. In an embodiment, the gate driver 120 of FIG. 1 may be mounted on the display panel DP and may be located in the non-display area NDA. In another embodiment, the gate driver 120 may be implemented as an integrated circuit separated from the display panel DP. In an embodiment, the temperature sensor 160 may be located in the non-display area NDA to sense a temperature of the display panel DP.

The pads PD may be located in the non-display area NDA on the substrate SUB. The pads PD may be electrically connected to the pixels PXL through lines. For example, the pads PD may be connected to the pixels PXL through the first to n-th data lines DL1 to DLn.

The pads PD may serve as an interface between the display panel DP and other components of the display device 100 (refer to FIG. 1). In an embodiment, voltages and signals required for operating the components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be supplied from the driver integrated circuit DIC through the pads PD. For example, the gate control signal GCS may be transmitted from the driver integrated circuit DIC to the gate driver 120 through the pads PD when the gate driver 120 is mounted on the display panel DP.

In an embodiment, a circuit board may be electrically connected to the pads PD using a conductive adhesive material such as an anisotropic conductive film. In this case, the circuit board may be a flexible circuit board (FPCB) or a flexible film having a flexible material. The driver integrated circuit DIC may be mounted on the circuit board and electrically connected to the pads PD.

In an embodiment, the display area DA may have various shapes. The display area DA may have a closed loop shape including straight and/or curved sides. For example, the display area DA may have shapes such as a polygon, a circle, a semicircle, and an ellipse.

In an embodiment, the display panel DP may have a flat display surface. In another embodiment, the display panel DP may have a display surface which is at least partially round. In an embodiment, the display panel DP may be bendable, foldable, or rollable. In such cases, the display panel DP and/or the substrate SUB may include materials having a flexible property.

FIG. 4 is a plan view schematically illustrating an embodiment of a pixel.

Referring to FIG. 4, the pixel PXL may include a first pixel PA and a second pixel PB. The first pixel PA may be a pixel having a relatively wide viewing angle. The second pixel PB may be a pixel having a viewing angle narrower than the viewing angle of the first pixel PA. The first pixel PA may emit light in the normal mode, and the second pixel PB may emit light in the private mode. For example, the first pixel PA may not emit light in the private mode, and the second pixel PB may not emit light in the normal mode. Accordingly, in the normal mode, an image with a standard viewing angle may be displayed, and in the private mode, an image with a relatively restricted viewing angle may be displayed, preventing visibility from certain directions, such as a side of the display panel DP. However, the operation of the normal and private modes is not limited to this configuration. In an embodiment, both the first pixel PA and the second pixel PB may emit light in the normal mode.

The first pixel PA may include a first sub-pixel PA1, a second sub-pixel PA2, and a third sub-pixel PA3. The first sub-pixel PA1, the second sub-pixel PA2, and the third sub-pixel PA3 may be spaced apart from each other in the first direction DR1 and/or the second direction DR2 in a plan view. The size and shape of the first to third sub-pixels PA1, PA2, and PA3 of the first pixel PA are not limited to the embodiment illustrated in FIG. 4 and may be modified to have various sizes and shapes.

The first sub-pixel PA1 of the first pixel PA may be an area where light is emitted from a first light emitting layer ELA1 located in the first sub-pixel PA1. The first light emitting layer ELA1 of the first pixel PA may generate light of a first color, for example, a red color. The first sub-pixel PA1 of the first pixel PA may be a sub-pixel of the first color, for example, the red color.

The second sub-pixel PA2 of the first pixel PA may be an area where light is emitted from a second light emitting layer ELA2 located in the second sub-pixel PA2. The second light emitting layer ELA2 of the first pixel PA may generate light of a second color, for example, a green color. The second sub-pixel PA2 of the first pixel PA may be a sub-pixel of the second color, for example, the green color. The second sub-pixel PA2 of the first pixel PA may include second sub-pixels. For example, the second sub-pixel PA2 of the first pixel PA may include two second sub-pixels, and the two second sub-pixels PA2 may be spaced apart from each other in the second direction DR2, but are not necessarily limited thereto.

The third sub-pixel PA3 of the first pixel PA may be an area where light is emitted from a third light emitting layer ELA3 located in the third sub-pixel PA3. The third light emitting layer ELA3 of the first pixel PA may generate light of a third color, for example, a blue color. The third sub-pixel PA3 of the first pixel PA may be a sub-pixel of the third color, for example, the blue color.

The second pixel PB may include a first sub-pixel PB1, a second sub-pixel PB2, a third sub-pixel PB3, and/or a light sensing pixel PO. The first sub-pixel PB1, the second sub-pixel PB2, the third sub-pixel PB3, and/or the light sensing pixel PO of the second pixel PB may be spaced apart from each other in the first direction DR1 and/or the second direction DR2 in a plan view. The size and shape of the first to third sub-pixels PB1, PB2, and PB3 of the second pixel PB and/or the light sensing pixel PO are not limited to the embodiment illustrated in FIG. 4 and may be modified to have various sizes and shapes.

The first sub-pixel PB1 of the second pixel PB may be an area where light is emitted from a first light emitting layer ELB1 located in the first sub-pixel PB1. The first light emitting layer ELB1 of the second pixel PB may generate light of the first color, for example, the red color. The first sub-pixel PB1 of the second pixel PB may emit light of the same color as the first sub-pixel PA1 of the first pixel PA. For example, the first sub-pixel PB1 of the second pixel PB may be a sub-pixel of the first color, for example, the red color.

The second sub-pixel PB2 of the second pixel PB may be an area where light is emitted from a second light emitting layer ELB2 located in the second sub-pixel PB2. The second light emitting layer ELB2 of the second pixel PB may generate light of the second color, for example, the green color. The second sub-pixel PB2 of the second pixel PB may emit light of the same color as the second sub-pixel PA2 of the first pixel PA. For example, the second sub-pixel PB2 of the second pixel PB may be a sub-pixel of the second color, for example, the green color. The second sub-pixel PB2 of the second pixel PB may include second sub-pixels. For example, the second sub-pixel PB2 of the second pixel PB may include two second sub-pixels, and the two second sub-pixels PB2 may be spaced apart from each other in the second direction DR2, but are not necessarily limited thereto.

The third sub-pixel PB3 of the second pixel PB may be an area where light from a third light emitting layer ELB3 positioned in the third sub-pixel PB3 is emitted. The third light emitting layer ELB3 of the second pixel PB may generate light of the third color, for example, the blue color. The third sub-pixel PB3 of the second pixel PB may emit light of the same color as the third sub-pixel PA3 of the first pixel PA. For example, the third sub-pixel PB3 of the second pixel PB may be a sub-pixel of the third color, for example, the blue color.

The light sensing pixel PO may sense a user's fingerprint or the like. For example, the light sensing pixel PO may sense light emitted from a light source and reflected by a user's finger or the like. Hereinafter, the disclosure is described based on an embodiment in which the light sensing pixel PO is used for fingerprint sensing, but is not necessarily limited thereto. For example, the light sensing pixel PO may sense various pieces of biometric information including blood pressure. In addition, the light sensing pixel PO may sense external light and may serve as a gesture sensor, a motion sensor, a proximity sensor, an illuminance sensor, an image sensor, or the like.

In an embodiment, the light sensing pixel PO may include light sensing pixels. For example, the light sensing pixel PO may include two light sensing pixels, and the two light sensing pixels PO may be spaced apart from each other in a diagonal direction between the first direction DR1 and the second direction DR2, but are not necessarily limited thereto.

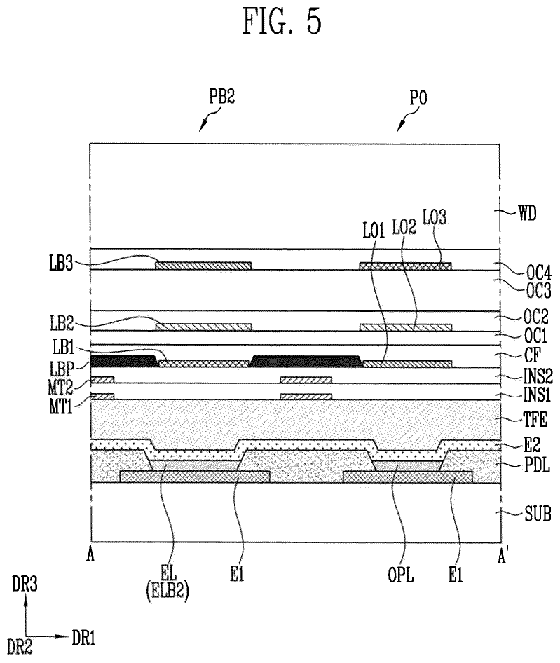

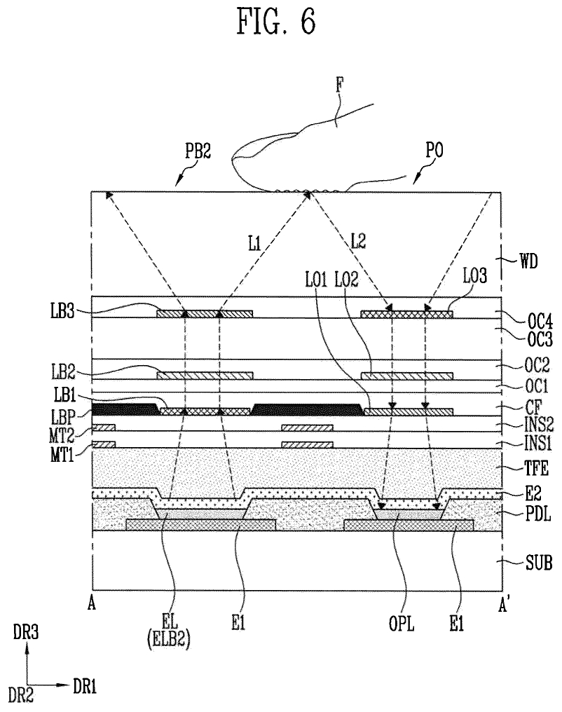

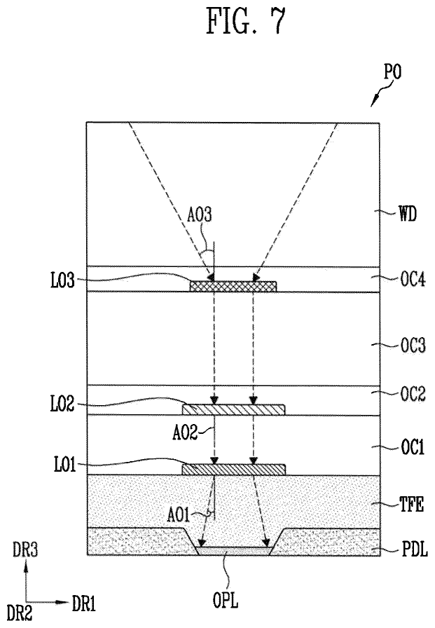

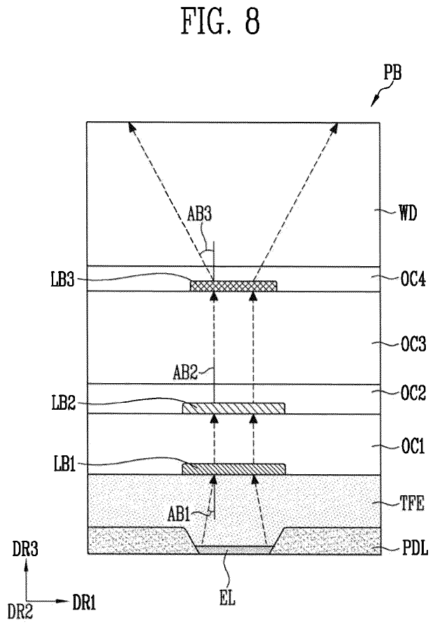

FIGS. 5 and 6 are cross-sectional views taken along line A-A′ of FIG. 4. FIG. 7 is a cross-sectional view schematically illustrating a light sensing pixel. FIG. 8 is a cross-sectional view schematically illustrating a second pixel. FIG. 9 is a cross-sectional view schematically illustrating a first pixel. FIGS. 7 to 9 are cross-sectional views illustrating meta lenses LO1, LO2, LO3, LB1, LB2, and LB3 in detail, and some configurations are omitted.

Referring to FIGS. 5 to 9, a light emitting element (E1, EL, and E2 sequentially stacked) and a light receiving element (E1, OPL, and E2 sequentially stacked) may be located on the substrate SUB. The substrate SUB may include a base layer and a circuit layer. The base layer may include polyimide (PI), glass, a silicon wafer, or the like. The circuit layer may include conductive patterns and insulating layers, and the conductive patterns may function as the pixel circuit (refer to SPC of FIG. 2) and various lines. The circuit layer may include transistors and one or more capacitors. Each transistor may include a semiconductor portion including a source area, a drain area, and a channel area, and a gate electrode overlapped with the semiconductor portion. Each capacitor may include electrodes spaced apart from each other in a third direction DR3 with an insulating layer between the electrodes. The lines of the circuit layer may include signal lines, for example, a gate line, an emission control line, a data line, and the like.

The light emitting element (E1, EL, and E2 sequentially stacked) may include an anode electrode (or a first electrode) E1, a light emitting layer EL, and/or a cathode electrode (or a second electrode) E2. The anode electrodes E1 may be electrically connected to the circuit layer of the substrate SUB. The anode electrodes E1 may include an opaque conductive material capable of reflecting light, but embodiments are not limited thereto.

Each of the anode electrodes E1 may be located in the sub-pixels PA1, PA2, PA3, PB1, PB2, and PB3 of the first and second pixels PA and PB and the light sensing pixel PO. Each of the anode electrodes E1 may have a shape similar to the sub-pixels PA1, PA2, PA3, PB1, PB2, and PB3 of the first and second pixels PA and PB and the light sensing pixel PO in a plan view.

A pixel defining layer PDL may be located on the anode electrodes E1. The pixel defining layer PDL may be located in a non-emission area NEA. The pixel defining layer PDL may include openings exposing a portion of each of the anode electrodes E1. The openings of the pixel defining layer PDL may define the sub-pixels PA1, PA2, PA3, PB1, PB2, and PB3 of the first and second pixels PA and PB and the light sensing pixel PO.

The light emitting layer EL may be located on the anode electrodes E1 and the pixel defining layer PDL. The light emitting layer EL may be located in each of the sub-pixels PA1, PA2, PA3, PB1, PB2, and PB3 of the first and second pixels PA and PB.

The first light emitting layer ELA1 of the first pixel PA and the first light emitting layer ELB1 of the second pixel PB are located in a same layer and may be formed simultaneously in a same process, but are not necessarily limited thereto. The first light emitting layer ELA1 of the first pixel PA and the first light emitting layer ELB1 of the second pixel PB may generate light of the first color, for example, the red color.

The second light emitting layer ELA2 of the first pixel PA and the second light emitting layer ELB2 of the second pixel PB are located in a same layer and may be formed simultaneously in a same process, but are not necessarily limited thereto. The second light emitting layer ELA2 of the first pixel PA and the second light emitting layer ELB2 of the second pixel PB may generate light of the second color, for example, the green color.

The third light emitting layer ELA3 of the first pixel PA and the third light emitting layer ELB3 of the second pixel PB are located in a same layer and may be formed simultaneously in a same process, but are not necessarily limited thereto. The third light emitting layer ELA3 of the first pixel PA and the third light emitting layer ELB3 of the second pixel PB may generate light of the third color, for example, the blue color.

A light receiving layer OPL may be located on the anode electrodes E1 and the pixel defining layer PDL. The light receiving layer OPL may be located in the light sensing pixel PO. In an embodiment, the light receiving layer OPL may include an organic photosensitive material. For example, the organic photosensitive material may include a dithiolene-based material (BDN) bis(4-dimethylaminodithiobenzyl)nickel(II), a benzotriazole-based polymer compound (PTZBTTT-BDT), a porphyrin-based small molecule material (DHTBTEZP), or the like, but is not necessarily limited to.

In an embodiment, the light receiving layer OPL may recognize a fingerprint by sensing light reflected by a ridge of a finger F and a valley between the ridges. For example, in case that a user's finger F touches a window WD, first light L1 emitted from the light emitting layer EL is reflected by the ridge (or the valley) of the finger F, and reflected second light L2 may reach the light receiving layer OPL. The light receiving layer OPL may recognize a pattern of the user's fingerprint by distinguishing the second light L2 reflected from the ridge of the finger F and the second light L2 reflected from the valley of the finger F.

The cathode electrode E2 may be located on the light emitting layer EL and the light receiving layer OPL. The cathode electrode E2 may be entirely located in the first pixel PA and the second pixel PB. The cathode electrode E2 may include a metal material or a transparent conductive material and have a relatively thin thickness. In an embodiment, the cathode electrode E2 may include at least one of various transparent conductive materials including indium tin oxide, indium zinc oxide, indium tin zinc oxide, aluminum zinc oxide, gallium zinc oxide, zinc tin oxide, or gallium tin oxide. In another embodiment, the cathode electrode E2 may include at least one of silver (Ag), magnesium (Mg), or a mixture thereof. However, a material of the cathode electrode E2 is not limited thereto.

An encapsulation layer TFE may be located on the cathode electrode E2. The encapsulation layer TFE may prevent oxygen, moisture, and/or the like from penetrating into the light emitting layer EL or the like. The encapsulation layer TFE may include a structure in which one or more inorganic layers and one or more organic layers are alternately stacked. The inorganic layers may include silicon nitride, silicon oxide, silicon oxynitride (SiOxNy), or the like. The organic layer may include an organic insulating material such as an acrylic resin, an epoxy resin, a phenol resin, a polyamide resin, a polyimide resin, an unsaturated polyester resin, a polyphenyleneether resin, a polyphenylenesulfide resin, or benzocyclobutene (BCB). However, materials of the organic layer and the inorganic layer of the encapsulation layer TFE are not limited thereto.

A first sensing conductive layer MT1 may be located on the encapsulation layer TFE. The first sensing conductive layer MT1 may be partially opened so as not to overlap the light emitting layer EL. An opening of the first sensing conductive layer MT1 may provide an optical path so that the first light L1 emitted from the light emitting layer EL can proceed to an upper portion of the display panel DP. In other words, the opening of the first sensing conductive layer MT1 may overlap the light emitting layer EL.

In addition, the first sensing conductive layer MT1 may be partially opened so as not to overlap the light receiving layer OPL. An opening of the first sensing conductive layer MT1 may provide an optical path so that the second light L2 reflected from the fingerprint of the user's finger F can proceed to the light receiving layer OPL. To this end, the opening of the first sensing conductive layer MT1 may be positioned to overlap with the light receiving layer OPL.

The first sensing conductive layer MT1 may include a metal layer or a transparent conductive layer. For example, the metal layer may include molybdenum, titanium, copper, aluminum, and an alloy thereof. The transparent conductive layer may include one of indium tin oxide (ITO), indium zinc oxide (IZO), zinc oxide (ZnO), indium tin zinc oxide (ITZO), PEDOT, and a metal nanowire, but is not necessarily limited to. The first sensing conductive layer MT1 may serve as a connection electrode that links sensing electrodes.

A first insulating layer INS1 may be located on the first sensing conductive layer MT1. The first insulating layer INS1 may include an inorganic insulating layer including an inorganic material or an organic insulating layer including an organic material. The inorganic insulating layer may include an inorganic insulator such as silicon oxide (SiOx), silicon nitride (SiNx), silicon oxynitride (SiOxNy), aluminum oxide (AlxOy), titanium oxide (TiOx), tantalum oxide (TaxOy), hafnium oxide (HfOx), or zinc oxide (ZnOx). The organic insulating layer may include at least one of an acrylic resin, a methacrylic resin, a polyisoprene, a vinyl resin, an epoxy resin, a urethane resin, a cellulose resin, a siloxane resin, a polyimide resin, a polyamide resin, or a perylene resin, but is not necessarily limited thereto.

A second sensing conductive layer MT2 may be located on the first insulating layer INS1. The second sensing conductive layer MT2 may be partially opened so as not to overlap the light emitting layer EL. An opening of the second sensing conductive layer MT2 may provide an optical path so that the first light L1 emitted from the light emitting layer EL can proceed to an upper portion of the display panel DP. In other words, the opening of the second sensing conductive layer MT2 may to overlap the light emitting layer EL.

In addition, the second sensing conductive layer MT2 may be partially opened so as not to overlap the light receiving layer OPL. An opening of the second sensing conductive layer MT2 may provide an optical path so that the second light L2 reflected from the fingerprint of the user's finger F can proceed to the light receiving layer OPL. To this end, the opening of the second sensing conductive layer MT2 may be positioned to overlap with the light receiving layer OPL.

The second sensing conductive layer MT2 may include a same material as the first sensing conductive layer MT1, or may include one or more materials selected from the materials exemplified as constituent materials of the first sensing conductive layer MT1.

The second sensing conductive layer MT2 may be electrically connected to the first sensing conductive layer MT1 through a contact hole passing through the first insulating layer INS1. The second sensing conductive layer MT2 may form sensing electrodes.

A second insulating layer INS2 may be located on the second sensing conductive layer MT2. The second insulating layer INS2 may include a same material as the first insulating layer INS1, or may include one or more materials selected from the materials exemplified as a constituent material of the first insulating layer INS1.

A first light emitting meta lens LB1 and/or a first light receiving meta lens LO1 may be located on the second insulating layer INS2. The first light emitting meta lens LB1 and/or the first light receiving meta lens LO1 may be located in a same layer. The first light emitting meta lens LB1 and/or the first light receiving meta lens LO1 may be formed simultaneously in a same process, but are/is not necessarily limited thereto. The first light emitting meta lens LB1 and/or the first light receiving meta lens LO1 may be formed through a lithography or imprinting process, but are/is not necessarily limited thereto.

In an embodiment, each of the first light emitting meta lens LB1 and/or the first light receiving meta lens LO1 may include a thin film and holes in the thin film. For example, each of the first light emitting meta lens LB1 and/or the first light receiving meta lens LO1 may include an inorganic thin film and holes formed in the inorganic thin film. The holes may be filled with a material having a specific refractive index or may be an empty space. A thickness in the third direction DR3 of the inorganic thin film may be 10 nm to 1 um. The inorganic thin film may include silicon (Si), gallium nitride (GaN), silicon nitride (SiNx), titanium oxide (TiOx), or the like. However, a structure, a shape, and/or a material of the first light emitting meta lens LB1 and/or the first light receiving meta lens LO1 may be varied based on considerations of the light path.

The first light emitting meta lens LB1 may be located in the second pixel PB. For example, the first light emitting meta lens LB1 may be located only in the second pixel PB. The first light emitting meta lens LB1 may not overlap the first pixel PA. The first light emitting meta lens LB1 may be located on the light emitting layer EL of each of the sub-pixels PB1, PB2, and PB3 of the second pixel PB. The first light emitting meta lens LB1 may overlap the light emitting layer EL of each of the sub-pixels PB1, PB2, and PB3 of the second pixel PB in the third direction DR3. The first light emitting meta lens LB1 may overlap the openings of the first and second sensing conductive layers MT1 and MT2 of each of the sub-pixels PB1, PB2, and PB3 of the second pixel PB in the third direction DR3.

The first light emitting meta lens LB1 may collect light in a first light emitting angle AB1 with respect to a normal line of the substrate SUB. In other words, the first light emitting meta lens LB1 may focus light within the first light emitting angle AB1 relative to the normal line of the substrate SUB. For example, the first light emitting meta lens LB1 may collect light emitted from the light emitting layer EL and incident in the first light emitting angle AB1 with respect to the normal line of the substrate SUB. The first light emitting angle AB1 may be 25°, but is not necessarily limited thereto. In this case, a width in the first direction DR1 of an opening of the pixel defining layer PDL of the sub-pixels PB1, PB2, and PB3 of the second pixel PB may be 14 um or less, but is not necessarily limited thereto. As described above, when the first light emitting meta lens LB1 is provided on the light emitting layer EL, it can control the light path emitted from the light emitting layer EL to improve front surface light emission efficiency of the private pixel, in other words, the second pixel PB.

The first light receiving meta lens LO1 may be located in the light sensing pixel PO. For example, the first light receiving meta lens LO1 may be located only in the light sensing pixel PO. The first light receiving meta lens LO1 may not overlap the first pixel PA.

The first light receiving meta lens LO1 may be located on the light receiving layer OPL. The first light receiving meta lens LO1 may overlap the light receiving layer OPL in the third direction DR3. Light incident on the first light receiving meta lens LO1 may be emitted at a first light receiving angle AO1 with respect to the normal line of the substrate SUB. For example, the first light receiving meta lens LO1 may refract or disperse light incident on the first light receiving meta lens LO1 at the first light receiving angle AO1 with respect to the normal line of the substrate SUB. The first light receiving angle AO1 may be 40° or less, but is not necessarily limited thereto. In this case, the width of the first direction DR1 of the opening of the pixel defining layer PDL of the light sensing pixel PO may be 8 um or less, but is not necessarily limited thereto.

As described above, when the first light receiving meta lens LO1 is provided on the light receiving layer OPL, it can control the path incident light on the light sensing pixel PO, thereby increasing the amount of light reaching the light receiving layer OPL and enhancing the signal.

A color filter CF may be located on the first light emitting meta lens LB1 and the first light receiving meta lens LO1. The color filter CF may overlap the light emitting layer EL and/or the light receiving layer OPL. The color filter CF may include a color filter material that matches the color of each of the sub-pixels PA1, PA2, PA3, PB1, PB2, and PB3.

In an embodiment, a light blocking layer LBP may be further located between each of the sub-pixels PA1, PA2, PA3, PB1, PB2, and PB3. The light blocking layer LBP may include openings overlapping the light emitting layer EL and/or the light receiving layer OPL. The opening of the light blocking layer LBP may provide an optical path so that the first light L1 emitted from the light emitting layer EL can proceed to an upper portion of the display panel DP. In addition, the opening of the light blocking layer LBP may provide an optical path so that the second light L2 reflected from the fingerprint of the user's finger F can proceed to the light receiving layer OPL. The color filter CF may be located in the opening of the light blocking layer LBP.

The light blocking layer LBP may include a light blocking material to prevent a color mixing defect. For example, the light blocking layer LBP may include a black matrix, but is not necessarily limited thereto. According to an embodiment, the light blocking layer LBP may include carbon black (CB) and/or titanium black (TiBK).

A first overcoat layer OC1 may be located on the color filter CF. The first overcoat layer OC1 may be entirely located in the first pixel PA and the second pixel PB. The first overcoat layer OC1 may prevent moisture or air from penetrating into a lower member. In addition, the first overcoat layer OC1 may protect the lower member from a foreign substance such as dust.

The first overcoat layer OC1 may include an organic material such as an acrylic resin, an epoxy resin, a phenolic resin, a polyamide resin, a polyimide resin, a polyester resin, a polyphenylenesulfide resin, or benzocyclobutene (BCB). However, the disclosure is not limited thereto, and the first overcoat layer OC1 may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

A second light emitting meta lens LB2 and/or a second light receiving meta lens LO2 may be located on the first overcoat layer OC1. The second light emitting meta lens LB2 and/or the second light receiving meta lens LO2 may be located in a same layer. The second light emitting meta lens LB2 and/or the second light receiving meta lens LO2 may be formed simultaneously in a same process, but are/is not necessarily limited thereto. In an embodiment, the second light emitting meta lens LB2 and/or the second light receiving meta lens LO2 may be formed through a lithography or imprinting process, but are/is not necessarily limited thereto.

In an embodiment, each of the second light emitting meta lens LB2 and/or the second light receiving meta lens LO2 may include a thin film and holes in the thin film. For example, each of the second light emitting meta lens LB2 and/or the second light receiving meta lens LO2 may include an inorganic thin film and holes formed in the inorganic thin film. The holes may be filled with a material having a specific refractive index or may be an empty space. A thickness in the third direction DR3 of the inorganic thin film may be 10 nm to 1 um. The inorganic thin film may include silicon (Si), gallium nitride (GaN), silicon nitride (SiNx), or titanium oxide (TiOx). However, a structure, a shape, and/or a material of the second light emitting meta lens LB2 and/or the second light receiving meta lens LO2 may be varied based on considerations of the light path.

The second light emitting meta lens LB2 may be located in the second pixel PB. For example, the second light emitting meta lens LB2 may be located only in the second pixel PB. The second light emitting meta lens LB2 may not overlap the first pixel PA.

The second light emitting meta lens LB2 may be located on the first light emitting meta lens LB1 (or the light emitting layer EL of each of the sub-pixels PB1, PB2, and PB3 of the second pixel PB). The second light emitting meta lens LB2 may overlap the first light emitting meta lens LB1 (or the light emitting layer EL of each of the sub-pixels PB1, PB2, and PB3 of the second pixel PB) in the third direction DR3.

Light incident on the second light emitting meta lens LB2 may be emitted at a second light emitting angle AB2 with respect to the normal line of the substrate SUB. The second light emitting angle AB2 may be less than the first light emitting angle AB1. For example, the second light emitting angle AB2 may be 0°, but is not necessarily limited thereto. For example, the second light emitting meta lens LB2 may emit light incident upon it as light parallel to the normal line of the substrate SUB, meaning straight light. As described above, when the second light emitting meta lens LB2 is provided on the light emitting layer EL (or on the first light emitting meta lens LB1), it can control the light path emitted from the light emitting layer EL to enhance the front surface light emission efficiency of the private pixel, in other words, the second pixel PB.

The second light receiving meta lens LO2 may be located in the light sensing pixel PO. The second light receiving meta lens LO2 may be located only in the light sensing pixel PO. The second light receiving meta lens LO2 may not overlap the first pixel PA.

The second light receiving meta lens LO2 may be located on the first light receiving meta lens LO1 (or the light receiving layer OPL). The second light receiving meta lens LO2 may overlap the first light receiving meta lens LO1 (or the light receiving layer OPL) in the third direction DR3.

Light incident on the second light receiving meta lens LO2 may be emitted at a second light receiving angle AO2 with respect to the normal line of the substrate SUB. The second light receiving angle AO2 may be less than the first light receiving angle AO1. For example, the second light receiving angle AO2 may be 0°, but is not necessarily limited thereto. For example, the second light receiving meta lens LO2 may emit the light incident on the second light receiving meta lens LO2 as light parallel to the normal line of the substrate SUB, meaning straight light. As described above, when the second light receiving meta lens LO2 is provided on the light receiving layer OPL (or on the first light receiving meta lens LO1), it can control the path of light incident on the light sensing pixel PO, thereby increasing the amount of light reaching the light receiving layer OPL and enhancing the signal.

A second overcoat layer OC2 may be located on the second light emitting meta lens LB2 and the second light receiving meta lens LO2. The second overcoat layer OC2 may be entirely located in the first pixel PA and the second pixel PB. The second overcoat layer OC2 may prevent moisture or air from penetrating into a lower member. In addition, the second overcoat layer OC2 may protect the lower member from a foreign substance such as dust.

The second overcoat layer OC2 may include an organic material such as an acrylic resin, an epoxy resin, a phenolic resin, a polyamide resin, a polyimide resin, a polyester resin, a polyphenylenesulfide resin, or benzocyclobutene (BCB). However, the disclosure is not necessarily limited thereto, and the second overcoat layer OC2 may include various types of inorganic materials including silicon oxide (SiOx), silicon nitride (SINx), silicon oxynitride (SiOxNy), aluminum nitride (AlNx), aluminum oxide (AIOx), zirconium oxide (ZrOx), hafnium oxide (HfOx), or titanium oxide (TiOx). The second overcoat layer OC2 may include a same material as the first overcoat layer OC1, but is not necessarily limited thereto.

A third overcoat layer OC3 may be located on the second overcoat layer OC2. The third overcoat layer OC3 may be entirely located in the first pixel PA and the second pixel PB. The third overcoat layer OC3 may prevent moisture or air from penetrating into a lower member. In addition, the third overcoat layer OC3 may protect the lower member from a foreign substance such as dust.

The third overcoat layer OC3 may include an organic material such as an acrylic resin, an epoxy resin, a phenolic resin, a polyamide resin, a polyimide resin, a polyester resin, a polyphenylenesulfide resin, or a benzocyclobutene (BCB).

A third light emitting meta lens LB3 and/or a third light receiving meta lens LO3 may be located on the third overcoat layer OC3. The third light emitting meta lens LB3 and/or the third light receiving meta lens LO3 may be located in a same layer. The third light emitting meta lens LB3 and/or the third light receiving meta lens LO3 may be formed simultaneously in a same process, but are/is not necessarily limited thereto. In an embodiment, the third light emitting meta lens LB3 and/or the third light receiving meta lens LO3 may be formed through a lithography or imprinting process, but are/is not necessarily limited thereto.

In an embodiment, each of the third light emitting meta lens LB3 and/or the third light receiving meta lens LO3 may include a thin film and holes in the thin film. For example, each of the third light emitting meta lens LB3 and/or the third light receiving meta lens LO3 may include an inorganic thin film and holes formed in the inorganic thin film. The holes may be filled with a material having a specific refractive index or may be an empty space. A thickness in the third direction DR3 of the inorganic thin film may be 10 nm to 1 μm. The inorganic thin film may include silicon (Si), gallium nitride (GaN), silicon nitride (SiNx), or titanium oxide (TiOx). However, a structure, a shape, and/or a material of the third light emitting meta lens LB3 and/or the third light receiving meta lens LO3 may vary based on considerations of the light path.

The third light emitting meta lens LB3 may be located in the second pixel PB. The third light emitting meta lens LB3 may be located only in the second pixel PB. The third light emitting meta lens LB3 may not overlap the first pixel PA.

The third light emitting meta lens LB3 may be located on the second light emitting meta lens LB2 (as well as the first light emitting meta lens LB1, and the light emitting layer EL of each of the sub-pixels PB1, PB2, and PB3 of the second pixel PB). The third light emitting meta lens LB3 may overlap the second light emitting meta lens LB2 (as well as the first light emitting meta lens LB1, and the light emitting layer EL of each of the sub-pixels PB1, PB2, and PB3 of the second pixel PB) in the third direction DR3.

Light incident on the third light emitting meta lens LB3 may be emitted at a third light emitting angle AB3 with respect to the normal line of the substrate SUB. For example, the third light emitting meta lens LB3 may refract or disperse the light incident upon it at the third light emitting angle AB3 with respect to the normal line of the substrate SUB. The third light emitting angle AB3 may be greater than the second light emitting angle AB2. For example, the third light emitting angle AB3 may be 25° or less. For example, the third light emitting angle AB3 may be 15° or less, but is not necessarily limited thereto. Light leakage may occur at a side viewing angle in the private mode if the third light emitting angle AB3 is excessively large.

As described above, when the third light emitting meta lens LB3 is provided on the light emitting layer EL (as well as the second light emitting meta lens LB2, and the first light emitting meta lens LB1), it can control the path of the light emitted from the light emitting layer EL to enhance the front surface light emission efficiency of the private pixel, specifically the second pixel PB.

The third light receiving meta lens LO3 may be located in the light sensing pixel PO. For example, the third light receiving meta lens LO3 may be located only in the light sensing pixel PO. The third light receiving meta lens LO3 may not overlap the first pixel PA.

The third light receiving meta lens LO3 may be located on the first light receiving meta lens LO1 (as well as the second light receiving meta lens LO2, and the light receiving layer OPL). The third light receiving meta lens LO3 may overlap the first light receiving meta lens LO1 (as the second light receiving meta lens LO2, and the light receiving layer OPL) in a third direction DR3. The third light receiving meta lens LO3 may collect light in a third light receiving angle AO3 with respect to the normal line of the substrate SUB. For example, the third light receiving meta lens LO3 may collect light incident from the outside at the third light receiving angle AO3 with respect to the normal line of the substrate SUB. The third light receiving angle AO3 may be greater than the second light receiving angle AO2. The third light receiving angle AO3 may be 60°. The third light receiving angle AO3 may be 30°, but is not necessarily limited thereto. Sensing performance may be reduced if the third light receiving angle AO3 is excessively small.

As described above, when the third light receiving meta lens LO3 is provided on the light receiving layer OPL (as well as the second light receiving meta lens LO2, and the first light receiving meta lens LO1), it can control the path of incident light on the light sensing pixel PO to increase the amount of light reaching the light receiving layer OPL, thereby enhancing the signal.

A fourth overcoat layer OC4 may be located on the third light emitting meta lens LB3 and/or the third light receiving meta lens LO3. The fourth overcoat layer OC4 may be entirely located the first pixel PA and the second pixel PB. The fourth overcoat layer OC4 may prevent moisture or air from penetrating into a lower member. In addition, the fourth overcoat layer OC4 may protect a lower member from a foreign substance such as dust.

The fourth overcoat layer OC4 may include an organic material such as an acrylic resin, an epoxy resin, a phenolic resin, a polyamide resin, a polyimide resin, a polyester resin, a polyphenylenesulfide resin, or a benzocyclobutene (BCB). However, the disclosure is not necessarily limited thereto, and the fourth overcoat layer OC4 may include various types of inorganic materials including silicon oxide (SiOx), silicon nitride (SINx), silicon oxynitride (SiOxNy), aluminum nitride (AlNx), aluminum oxide (AIOx), zirconium oxide (ZrOx), hafnium oxide (HfOx), or titanium oxide (TiOx).

A window WD may be provided on the fourth overcoat layer OC4. The window WD may protect a lower member from external impact and provide an input surface and/or a display surface to a user.

According to the embodiment described above, the light emitting meta lenses LB1, LB2, and LB3 positioned in the sub-pixels PB1, PB2, and PB3 of the second pixel PB, which serves as the private pixel, can control the light path emitted from the light emitting layer EL, thereby improving front surface light emission efficiency in the private mode. In addition, by limiting the viewing angle of the second pixel PB using the light emitting meta lenses LB1, LB2, and LB3, a light blocking layer or similar structure for implementing the private mode may be omitted. As a result, a high-resolution display device can be achieved without resolution limitations caused by the presence of a light-blocking layer.

In addition, according to the embodiment described above, placing the light receiving meta lenses LO1, LO2, and LO3 in the light sensing pixel PO allows control of the light incident path, increasing the amount of light reaching the light receiving layer OPL. As a result, the signal strength is enhanced, thereby mitigating sensing performance reduction in the private mode.

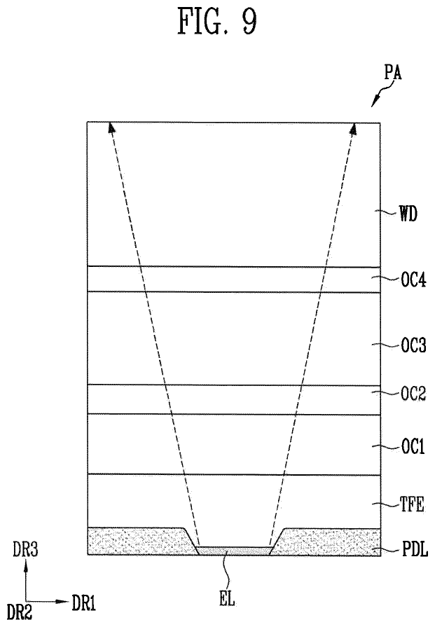

FIG. 10 is a perspective view schematically illustrating an application example of the display device.

Referring to FIG. 10, the display device according to the embodiment described above may be applied to an automotive display. For example, the automotive display may refer to an electronic device installed inside or outside a vehicle that provides image data.

For example, the display device may be applied to at least one of an infotainment panel 141, a cluster 142, a co-driver display 143, a head-up display 144, a side mirror display 145, or a rear seat display 146 provided in a vehicle. For example, the display device may be applied to the co-driver display 143 and may be switched to the private mode during driving. In this case, because the co-driver display 143 may not be visible from a driver's seat, a driver's gaze may be prevented from being distracted even though a passenger in a passenger seat uses the co-driver display 143 during driving. The automotive display is not limited to the embodiment shown in FIG. 10. The infotainment panel 141, the cluster 142, and/or the co-driver display 143 may be integrated into a single display. Additionally, a driver's seat area may operate in the normal mode and a passenger seat area may be configured to switch between the normal mode and the private mode.

A display device according to an embodiment can be applied to various types of electronic devices. In an embodiment, an electronic device includes the above-described display device and may further include additional modules or components that provide further functionalities.

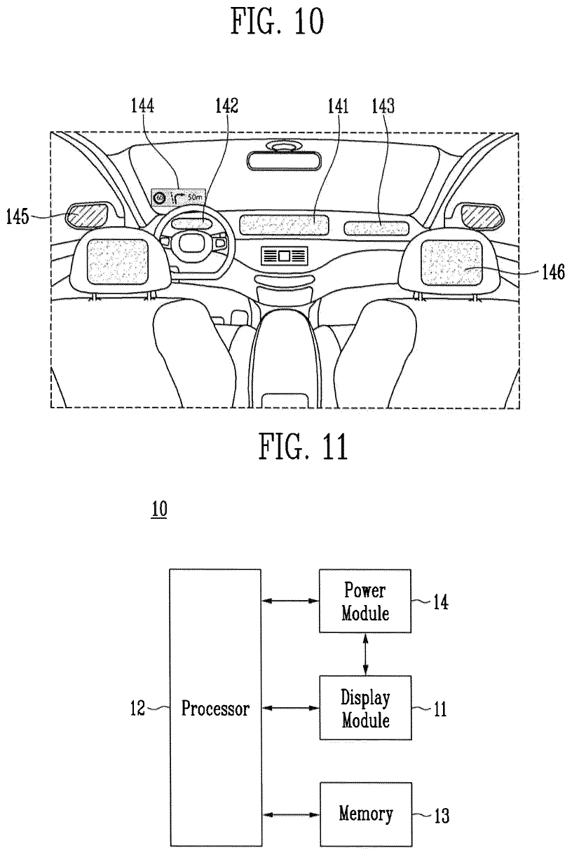

FIG. 11 is a block diagram of an electronic device according to an embodiment. Referring to FIG. 11, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, certain individual modules within a single module may be integrated into the display device, while others may be provided separately. For example, the display module 11 is included in the display device, whereas the processor 12, the memory 13, and the power module 14 are not included in the display device and are instead provided separately in the electronic device 10.

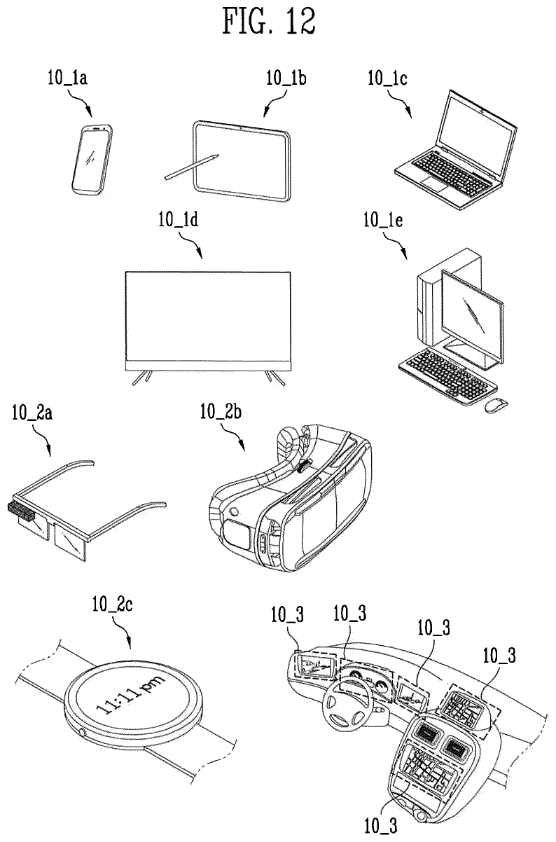

FIG. 12 shows schematic views of various embodiments of an electronic device.

Referring to FIG. 12, embodiment of the display device may be applied to various types of electronic devices. These include image-displaying electronic devices such as a smartphone 10_1a, a tablet PC 10_1b, a laptop computer 10_1c, a television (TV) 10_1d, and a desktop monitor 10_1e. They also include wearable electronic devices with display modules, such as smart glasses 10_2a, a head-mounted display (HMD) 10_2b, and a smart watch 10_2c. Additionally, the display device may be applied to automotive electronic device 10_3, including a display module such as a center information display (CID) positioned in the instrument cluster, center fascia, dashboard, or a room mirror display within a vehicle.

Although specific embodiments and application examples have been described herein, other embodiments and modifications may be derived from the above description. Therefore, the scope of this disclosure is not limited to these embodiments but extends to the claims set forth below, along with various modifications, and equivalents.

What is claimed is:

1. A display device comprising:
a substrate including a sub-pixel including a light emitting layer and a light sensing pixel including a light receiving layer;
a first light receiving meta lens overlapping the light receiving layer; and
a second light receiving meta lens overlapping the first light receiving meta lens,
wherein light incident on the first light receiving meta lens is emitted at a first light receiving angle with respect to a normal line of the substrate,
light incident on the second light receiving meta lens is emitted at a second light receiving angle with respect to the normal line of the substrate, and
the first light receiving angle is greater than the second light receiving angle.

2. The display device according to claim 1, wherein the first light receiving meta lens overlaps the second light receiving meta lens.

3. The display device according to claim 1, wherein each of the first light receiving meta lens and the second light receiving meta lens includes a thin film, and holes in the thin film.

4. The display device according to claim 1, wherein the first light receiving angle is 40° or less.

5. The display device according to claim 1, wherein the second light receiving angle is 0°.

6. The display device according to claim 1, further comprising:
a third light receiving meta lens overlapping the second light receiving meta lens.

7. The display device according to claim 6, wherein the third light receiving meta lens collects light at a third light receiving angle with respect to the normal line of the substrate, and
the third light receiving angle is greater than the second light receiving angle.

8. The display device according to claim 6, wherein the third light receiving angle is 60°.

9. The display device according to claim 6, wherein the third light receiving meta lens overlaps the first light receiving meta lens.

10. The display device according to claim 1, further comprising:
a first light emitting meta lens overlapping the light emitting layer; and
a second light emitting meta lens overlapping the first light emitting meta lens,
wherein the first light emitting meta lens collects light at a first light emitting angle with respect to the normal line of the substrate,
light incident on the second light emitting meta lens is emitted at a second light emitting angle with respect to the normal line of the substrate, and
the first light emitting angle is greater than the second light emitting angle.

11. The display device according to claim 10, wherein the first light emitting angle is 25°.

12. The display device according to claim 10, wherein the second light emitting angle is 0°.

13. The display device according to claim 10, further comprising:
a third light emitting meta lens overlapping the second light emitting meta lens.

14. The display device according to claim 13, wherein light incident on the third light emitting meta lens is emitted at a third light emitting angle with respect to the normal line of the substrate, and
the third light emitting angle is greater than the second light emitting angle.

15. A display device comprising:
a first pixel and a second pixel having a viewing angle narrower than a viewing angle of the first pixel,
wherein the second pixel comprises:
a sub-pixel including a light emitting layer;
a light sensing pixel including a light receiving layer;
a first light emitting meta lens overlapping the light emitting layer;
a second light emitting meta lens overlapping the first light emitting meta lens;
a first light receiving meta lens overlapping the light receiving layer; and
a second light receiving meta lens overlapping the first light receiving meta lens.

16. The display device according to claim 15, wherein the first light emitting meta lens and the first light receiving meta lens are located in a same layer.

17. The display device according to claim 15, wherein the second light emitting meta lens and the second light receiving meta lens are located in a same layer.

18. The display device according to claim 15, wherein the first light emitting meta lens and the second light receiving meta lens do not overlap the first pixel.

19. The display device according to claim 15, wherein the first light receiving meta lens and the second light receiving meta lens do not overlap the first pixel.

20. An electronic device comprising:
a display panel including a first pixel and a second pixel having a viewing angle narrower than a viewing angle of the first pixel,
wherein the second pixel comprises:
a sub-pixel including a light emitting layer;
a light sensing pixel including a light receiving layer;
a first light emitting meta lens overlapping the light emitting layer;
a second light emitting meta lens overlapping the first light emitting meta lens;
a first light receiving meta lens overlapping the light receiving layer; and
a second light receiving meta lens overlapping the first light receiving meta lens.
